(19) United States
(12) Patent Application Publication
(10) Pub. No.: US 2014/0273407 A1
(43) Pub. Date: Sep. 18, 2014

(54) Formulations And Methods For Surface Cleaning And Passivation of CdTe Substrates

(71) Applicant: First Solar, Inc., Perrysburg, OH (US)

(72) Inventors: Scott Christensen, Perrysburg, OH (US); Scott Jewhurst, Redwood City, CA (US); Minh Huu Le, San Jose, CA (US); Haifan Liang, Fremont, CA (US); Hao Lin, Santa Clara, CA (US); Wei Liu, Sunnyvale, CA (US); Minh Anh Nguyen, San Jose, CA (US); Zhi Wen Sun, Sunnyvale, CA (US); Gang Xiong, Santa Clara, CA (US)

(73) Assignee: FIRST SOLAR, INC., Perrysburg, OH (US)

(21) Appl. No.: 14/211,658

(22) Filed: Mar. 14, 2014

Related U.S. Application Data
(60) Provisional application No. 61/785,580, filed on Mar. 14, 2013.
(60) Provisional application No. 61/785,637, filed on Mar. 14, 2013.

(51) Int. Cl. H01L 31/18

(52) U.S. Cl. CPC H01L 31/1868
USPC 438/476; 106/1.11; 510/175

(57) ABSTRACT

Methods and compositions for the surface cleaning and passivation of CdTe substrates usable in solar cells are disclosed. In some embodiments amine-containing chelators are used and in other embodiments phosphorus-containing chelators are used.

### RELATED APPLICATIONS

This application claims priority from U.S. provisional application Ser. No. 61/785,580, filed on Mar. 14, 2013; and from U.S. provisional application Ser. No. 61/785,637, also filed on Mar. 14, 2013, both pending and both bearing the title “Formulations and Methods for Surface Cleaning and Passivation of CdTe Substrates.” Both of the above-mentioned provisional applications are incorporated herein by reference in their entirety.

### STATEMENT REGARDING FEDERALLY SPONSORED RESEARCH

The invention was not made with any government support and the government has no rights in the invention.

### TECHNICAL FIELD

The present invention relates to the field of surface cleaning and passivating semiconductor materials, such as CdTe substrates usable in solar cells.

### BACKGROUND OF THE INVENTION

CdTe has proven to be a desirable material in the manufacturing of solar cells, due to its low-cost and optimal band structure. A typical process to manufacture a CdTe solar cell starts with a glass substrate and a transparent conducting oxide (TCO) layer—such as tin oxide, indium tin oxide, or cadmium stannate—being placed on the substrate. Then, a thin layer of material such as CdS, doped to create an n-type material wherein the majority of charge carriers within the layer are electrons, is deposited onto the TCO surface. CdS has a wide enough band gap to allow most incident solar radiation through the CdS layer, thereby serving as a transparent, or window, layer. A p-type layer of CdTe, wherein the majority of charge carriers are holes, is then deposited on top of the CdS layer, and usually annealed at about 400° C. in the presence of CdCl₂. The CdTe layer is generally thicker than the CdS layer, and absorbs the majority of incident light. Most of the charge carriers excited and freed by absorption are within the CdTe layer. An electric field is created by the charge imbalance at the p-n junction, and separates the freed charge carriers. Freed holes travel to the back contact, and freed electrons travel from the p-type material across the junction to the n-type material. Electrical contacts allow the current to be collected and flow to external circuits. The TCO layer serves as the front contact. A metallic layer placed onto the p-CdTe layer functions as the hack, or rear, contact.

The process of manufacturing CdTe solar cells, undertaken in a plant environment, inherently results in the surface of CdTe layers becoming contaminated from organic compounds, CdCl₂ residues, and surface oxides. Electrical performance of semiconductor materials is hindered by such surface contamination, resulting in decreased photovoltaic device performance.

Known attempts at solving this problem have included the use of chemical etching, which is based on chemical dissolution processes and is widely used in modern semiconductor manufacturing. Solutions of elemental bromine in organic or inorganic solvents such as ethanol, methanol, dimethylformamide, or hydrobromic acid, are among the most common surface etchants for CdTe. However, such wet chemical etchants result in non-stoichiometric surfaces. Known etching solutions and processes cause a preferential removal of Cd, thereby creating a stoichiometric excess of Te on the substrate. Commercially available surface cleaning solutions for CdTe include NP etch (nitric acid and phosphoric acid mixture) and BM etch (bromine dissolved in methanol). Such solutions always leave a Te-rich surface layer with various Te layer thicknesses up to about 5-10 nm thick. Thus, surface cleaning with the ability to control stoichiometry has not yet been realized. Moreover, strong etchants such as NP and BM tend to severely attack the grain boundary area, making etch time control difficult. Furthermore, bromine-based etchants exhibit instability in storage, making them less suitable for large-scale use.

Te-enriched CdTe surfaces (left by commercially available etching solutions like BM etch or NP etch) can undergo rapid oxidation to TeO₂ under ambient conditions. Te-rich CdTe films can also be seen from physical vapor deposition (PVD) due to higher Cd vapor pressure, and plating due to the need for p-type CdTe. Cd-enriched CdTe surfaces (left by strong alkaline etching solutions) can also easily oxidize to CdO or Cd(OH)₂. Surface oxidation is exacerbated by surface non-stoichiometry. Stoichiometric CdTe surfaces, on the other hand, behave like silicon. The native oxides, such as CdTeO₃, are limited to only about 10-20 Å under ambient conditions, and the diffusion-controlled oxidation rate is slow. It is thus advantageous for any cleaning or passivation method to allow for stoichiometric control.

Elemental Te is generally difficult to remove because of its stability over the entire pH range unless oxidized, reduced, or converted into soluble form by complexing agents. The elemental Te formed on CdTe, on the other hand, has a reduced stability range due to thermodynamic factors. Such Te can be removed at pH levels around 11-12 (i.e., in strong alkaline solutions). However, the dissolution rate of Te on CdTe is kinetically slow. Known methods of removing Te, such as anodic dissolution or cathodic reduction, also lack the ability to control surface stoichiometry. Te inevitably forms on CdTe during anodic dissolution, and oxidizes to soluble TeO₃²⁻, but a strong oxidizer is needed to remove these components. Additionally, strong reducing agents such as NaBH₄ or Na₂S₂O₄ are required to remove Te through cathodic reduction.

Similarly, known methods of CdTe surface passivation lack stoichiometric control. Such methods include electronic passivation to reduce the impact of surface states, and chemical passivation to create oxidation resistance in air. Known electronic passivation methods for CdTe include using larger bandgap materials such as dielectrics (e.g., ZnS, SiO₂, Si₃N₄), native films, and in-situ grown HgTe heterostructures with wider bandgap II-VI compounds (such as CdS). Known chemical passivation methods involve immersing the CdTe substrates in ammonium sulfide after BM etch. The BM etch results in the surface of the substrate being covered by Te/TeO₂. Electronic properties, including ohmicity, have been improved by immersing these substrates in (NH₄)₂Sₓ so as to remove the TeO₂ and form a surface layer of CdTe₁₋ₓSₓ, where x is between 0 and 1. This process passivates the surface because CdS has a higher oxidation resistance than CdTe. No bulk crystalline CdO phase can be detected up to 380° C. annealing in air, and surface Cd(OH)₂ formation is observed at room temperature only after relatively long humid air exposure of 72 hours. However, this surface passivation process requires expensive equipment and does not address the problem of CdTe surface oxidation in air.

It would be beneficial to develop methods of cleaning and passivating the surface of CdTe substrates that allow for surface stoichiometric optimization, so as to enable better device performance.

### BRIEF DESCRIPTION OF THE DRAWINGS

FIG. 1A shows SEM images of a CdTe film after an extended duration ethylenediamine (ED) cleaning at room temperature. FIG. 1B shows energy-dispersive X-ray spectroscopy (EDX) analysis of a CdTe film after an extended duration ED cleaning at room temperature.

FIG. 2A is a graph of the time needed for CdTe removal in ED+H₂O₂ solutions as a function of pH. FIG. 2B is a graph showing the CdTe etch rate of a 1.0 M ED+2 vol. % H₂O₂ solution as a function of pH.

FIG. 3 is a graph displaying the surface ratio of Cd to Te on CdTe substrates after cleaning with HCl, nitrilotri(methylphosphonic) acid (NTMP), and a mixture of etidronic acid and 1-hydroxyethane-1,1-diphosphonic acid (HEDP) solutions. The graph shows a stoichiometric surface can be obtained from a NTMP bath between about pH 10 and about pH 11.

FIG. 4 is a graph demonstrating the efficiency of CdTe substrates with varying Cd:Te surface ratios obtained from cleaning with a 0.5 M NTMP bath and a 0.5 M HEDP bath.

FIG. 5 is a graph displaying the percent Te oxide in total Te present on a CdTe substrate after cleaning with HCl, NTMP, and HEDP, respectively, followed by 30 minutes of air exposure. The graph shows the NTMP solution around pH 11 removed almost all of the Te oxide present.

FIG. 6 shows X-ray photoelectron spectroscopy (XPS) spectra obtained from CdTe substrates cleaned by HCl, HEDP, and NTMP. Peaks around 133 eV are the signature of phosphate species. These spectra reveal organic phosphate absorption, indicating a low amount of phosphates remaining on the CdTe surface after cleaning.

### DETAILED DESCRIPTION OF THE INVENTION

Various embodiments are described herein in the context of methods and compositions for surface cleaning and passivation of CdTe substrates usable in solar cells. Those of ordinary skill in the art will realize that the following detailed description of the embodiments is illustrative only and not intended to be in any way limiting. Other embodiments will readily suggest themselves to such skilled persons having the benefit of this disclosure. Reference to an “embodiment,” “aspect,” or “example” herein indicate that the embodiments of the invention so described may include a particular feature, structure, or characteristic, but not every embodiment necessarily includes the particular feature, structure, or characteristic. Further, repeated use of the phrase “in one embodiment” does not necessarily refer to the same embodiment, although it may.

In the interest of clarity, not all of the routine features of the implementations or processes described herein are shown and described. It will, of course, be appreciated that in the development of any such actual implementation, numerous implementation-specific decisions will be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking for those of ordinary skill in the art having the benefit of this disclosure.

The term “alkyl” as used herein refers to monovalent alkyl groups, which are saturated hydrocarbons, preferably having from 1 to 10 carbon atoms and more preferably 1 to 6 carbon atoms. This term is exemplified by groups such as methyl, ethyl, n-propyl, iso-propyl, n-butyl, iso-butyl, n-hexyl, and the like. The term “aryl” as used herein refers to refers to an unsaturated aromatic carbocyclic group of from 6 to 14 carbon atoms having a single ring (e.g., phenyl) or multiple condensed rings (e.g., naphthyl or anthryl). Preferred aryls include phenyl, naphthyl and the like.

The term “amines” as used herein refers to compounds containing a basic nitrogen atom having a lone pair of electrons. Amines can be organic or inorganic compounds, and include primary, secondary, tertiary, and cyclic amines. The term “amine derivatives” as used herein refers to a broad scope of nitrogen-containing organic compounds such as amides, salts of amines, and aniline derivatives. The term “metal amine complex” or “metal amine complex” as used herein refers to a metal complex containing at least one NH₃ ligand. The term “thiol” as used herein refers to an organosulfur compound containing a R—SH group, where R is a carbon-containing group.

Though CdTe substrates are specified in this disclosure for ease of explanation, the skilled practitioner will appreciate that the methods and compositions described herein can be used for the surface cleaning and/or passivation of any II-VI semiconductor material. Such materials comprise cadmium, beryllium, magnesium, zinc, selenium, mercury, tellurium, zinc, sulfur, or combinations thereof. Examples of other II-VI semiconductor materials include ZnS, ZnSe, ZnTe, CdS, CdSe, and HgTe. CdTe substrates are but one example of a II-VI semiconductor material.

The term “Cd chelator” as used herein refers to a compound that chelates to Group II elements, such as Cd, preferentially over Group VI elements, such as Te. The term “Te chelator” as used herein refers to a compound that chelates to Group VI elements, such as Te, preferentially over Group II elements, such as Cd.

### Amine-Containing Chelator Compounds

Provided herein are methods and compositions for the surface cleaning and passivation of semiconductor materials, such as CdTe substrates usable in solar cells. The steps of surface cleaning and passivation may be performed separately in a sequential manner, individually with only surface cleaning or only surface passivation, or together simultaneously. A single wet chemical bath for both surface cleaning and passivation is provided for the simultaneous surface cleaning and passivation. Alternatively, separate cleaning and passivation baths are provided for individual surface cleaning or surface passivation or both surface cleaning and passivation in a sequential manner. A method for sequential surface cleaning and passivation involves subjecting CdTe substrates with a surface cleaning bath, then subjecting the CdTe substrates to a passivation bath. Optionally, after either the simultaneous or the sequential surface cleaning and passivation, the cleaned and passivated CdTe substrates can be subjected to Ar sputtering or a plasma cleaning step to further improve the surface cleaning and passivation. Other suitable cleaning steps, such as exposing the CdTe substrates to ultraviolet radiation, are also possible.

A single wet bath for both surface cleaning and passivation of CdTe substrates comprises a first chelating agent component selected from an amine, an amine derivative, or mixtures thereof; a second chelating agent component, as needed, comprising a poly-hydroxy-carboxylic acid; an oxidizer; and a surface passivation component, as needed, comprising a source of sulfur. The first chelating agent component is a Cd chelator, and the second chelating agent component is a Te chelator.

The first chelating agent component is generally present in a concentration ranging from about 0.02 M to about 1M, or more particularly about 0.2 M to about 0.5 M, and is selected from suitable amines, amine derivatives, and mixtures thereof. Suitable amines and amine derivatives include, but are not limited to, polyamines such as ethylenediamine, diethylenetriamine, triethylenetetramine, tetraethylenepentaamine, or pentaethylenehexamine; amino-carboxylic acids such as ethylenediamine tetraacetic acids, iminodiacetic acid, nitriloacetic acid, hydroxyethylenediaminetriacetic acid, or diethylenetriaminepentaacetic acid; poly-alcohol amines such as ethanolamines, including but not limited to monoethanolamine, diethanolamine, triethanolamine, or 1,2-diphenylethanolamine; or metal amine complexes such as borane-dimethylamine.

The second chelating agent component, if present, includes one or more poly-hydroxy-carboxylic acids. Suitable poly-hydroxy-carboxylic acids contain from 1 to 3 hydroxyl groups and from 1 to 3 carboxyl groups. In certain embodiments, the second chelating agent component is citric acid, isocitric acid, tartaric acid, glycolic acid, or a mixture thereof. The second chelating agent component may be present in a concentration ranging from about 0.02 M to about 1 M, or more particularly from about 0.1 M to about 0.5 M, such as 0.2 M.

The surface passivation component, if present, includes a source of sulfur. In certain embodiments, the source of sulfur is an organic sulfur-containing compound, such as a thiol. Suitable organic sulfur-containing compounds include, but are not limited to, mercaptopropionic acid (MPA), thioglycerol (TGA), mercaptoethylamine (MEA), or mixtures thereof. In certain embodiments, the source of sulfur is an inorganic sulfur-containing compound or mixtures thereof, such as ammonium sulfide ((NH₄)₂S). Combinations of organic and inorganic sulfur-containing compounds are possible. The surface passivation component can also include a zinc salt, such as ZnSO₄, and one or more bases. Suitable bases include, but are not limited to, NaOH, KOH, tetramethylammonium hydroxide (TMAH), or combinations thereof.

The oxidizer in the cleaning and passivation bath, if present, generally comprises H₂O₂, but other oxidizers are possible. The oxidizer can be present in concentrations ranging from about 0 M to about 0.05 M. It should be noted that the presence of an oxidizer in the bath is not necessary to accomplish surface cleaning and/or passivation. The cleaning and passivation bath may further comprise additional pH modifiers. The cleaning and passivation bath can generally be used at temperatures ranging from about 0° C. to about 80° C., such as about 20° C., and at a pH ranging from about 9 to about 13.

Further provided herein are a method and composition for the surface cleaning of CdTe substrates usable in solar cells. The method involves washing CdTe substrates in a wet alkaline chemical cleaning bath. The alkaline chemical cleaning bath contains an oxidizer to remove organic contamination; a first chelating agent component that is a Cd chelator; and a second chelating agent component, if necessary, that is a Te chelator.

The first chelating agent component of the surface cleaning bath is generally present in a concentration ranging from about 0.02 M to about 1 M, or more particularly about 0.2 M to about 0.5 M. The first chelating agent component is selected from amines, amine derivatives, or mixtures thereof. Suitable amines and amine derivatives include, but are not limited to, polyamines such as ethylenediamine, diethylenetriamine, triethylenetetramine, tetraethylenepentaamine, or pentaethylenehexamine; amino-carboxylic acids such as ethylenediamine tetraacetic acids, iminodiacetic acid, nitriloacetic acid, hydroxyethylenediaminetriacetic acid, or diethylenetriaminepentaacetic acid; poly-alcohol amines such as ethanolamines, including but not limited to monoethanolamine, diethanolamine, triethanolamine, or 1,2-diphenylethanolamine; or metal amine complexes, such as borane-dimethylamine.

The second chelating agent component, if present, includes one or more poly-hydroxy-carboxylic acids having from 1 to 3 hydroxyl groups and from 1 to 3 carboxyl groups. Examples of suitable poly-hydroxy-carboxylic acids include, but are not limited to, citric acid, isocitric acid, tartaric acid, glycolic acid, and mixtures thereof. The second chelating agent component is present in a concentration ranging from about 0.02 M to about 1 M, or more particularly from about 0.1 M to about 0.5 M.

The oxidizer in the cleaning bath, if present, generally comprises H₂O₂, but other oxidizers are possible. It should be noted that the presence of an oxidizer in the bath is not necessary to accomplish surface cleaning. The surface cleaning bath may further comprise additional pH modifiers. The surface cleaning bath can generally be used at temperatures ranging from about 0° C. to about 80° C., such as about 20° C., and at a pH ranging from about 9 to about 13.

In one embodiment of the alkaline chemical cleaning bath, the first chelating agent component is ethylenediamine tetraacetic acid disodium salt (Na-EDTA), and is present at a concentration ranging from about 0.2 M to about 0.4 M. The pH of this embodiment of the cleaning bath can be adjusted by a KOH buffer, and ranges from about 11.5 to about 13.0. The oxidizer is H₂O₂ and is present at a concentration ranging from about 0 to about 0.044 M. This embodiment of the cleaning bath is relatively low-cost to prepare. When CdTe substrates are washed with this particular embodiment of the alkaline cleaning bath for a time period of from about 30 seconds to about 60 seconds, the alkaline cleaning bath shows strong chelating for Cd dissolution, and has a low probability for chemical residue due to low surface activity.

In another embodiment of the alkaline cleaning bath, the first chelating agent component is triethanolamine (TEA), and is present at a concentration ranging from about 1.0 M to about 2.0 M. The pH of the cleaning bath can be adjusted by a KOH buffer, and ranges from about 11.0 to about 12.5. The oxidizer is H₂O₂ and is present at a concentration ranging from about 0 to about 0.044 M. This embodiment of the cleaning bath is relatively low-cost to prepare and has low toxicity and few human health effects. When CdTe substrates are washed with this particular embodiment of the alkaline cleaning bath for a time period of from about 30 seconds to about 60 seconds, the alkaline cleaning bath has a low probability for chemical residue due to medium surface activity.

In order to adjust surface stoichiometry to a desired ratio, the Cd and Te removal rates can be tuned by varying the pH of the baths, the concentration of the chelating agent components, the concentration of oxidizers, and/or the temperature of the bath. In one example, there is provided a method for modulating the surface stoichiometry of a semiconductor material, involving subjecting the semiconductor material to a cleaning bath or a cleaning and passivation bath as described above, and adjusting the concentration of the second chelating agent in order to achieve a desired stoichiometric ratio on the surface of the semiconductor material. In another example, the pH of the cleaning bath can be adjusted to control the surface ratio of Cd to Te in a CdTe substrate. This is because cadmium tends to oxidize into Cd(OH)₂ and CdO faster at higher pH levels, and these compounds do not chelate as readily as Cd does. As a result, CdTe substrates tend to have Cd-rich surfaces at pH levels between about 11 and 13. Conversely, CdTe substrates tend to have Te-rich surfaces at pH levels below about 9. It is possible to achieve a stoichiometric surface using the baths of the present disclosure in the pH range of about 9 to about 12. Both control methods provide the ability to optimize back-contact surface chemical and electronic properties. For instance, surface stoichiometry control enables the use of various back-contact electrodes that would perform the best with different surface Cd:Te ratios.

Further, grain boundary attack during cleaning can be minimized by factors such as pH, chelating agent concentration, and the time duration for the surface cleaning and/or passivation process. Minimized grain boundary attack can reduce the chance of cell shunting, which may ultimately improve the panel manufacturing yield and produce higher currents by reducing the carrier recombination at the back contact.

The alkaline chemical surface cleaning bath and surface cleaning and passivation bath described herein allow for surface organic contamination removal and oxide removal in a single wet chemical bath. The removal of surface oxides can ultimately improve the efficiency of solar cells made from the cleaned substrates.

Surface passivation against re-oxidation in air of CdTe surfaces that have been wet-cleaned to remove organic contamination and surface oxides is desired in order to improve the overall solar cell manufacturing process robustness and the panel manufacturing yield. Provided herein are methods and compositions for the surface passivation of a CdTe substrate. A surface passivation step as described is a wet passivation step that replaces the CdTe surface of the substrate with a surface that is resistant to oxidation, such as a CdₓZnₓ₋₁S surface where x is between 0 and 1. This is accomplished by subjecting the CdTe substrate to a surface passivation bath as described below. Surface passivation in this manner can result in a more repeatable and flexible manufacturing process because the cleaned CdTe surface can be stored in air for extended periods of time without producing undesirable surface oxidation. A more robust manufacturing flow created by this method can result in a higher yield of panels produced.

A surface passivation bath in accordance with the present disclosure has several possible embodiments, such as a reducing agent bath, an inorganic sulfurization bath, or an organic sulfurization bath. As a reducing agent bath, the passivation bath comprises one or more reducing agents such as tetramethylammonium borohydride (TMA-BH₄), NaBH₄, or dimethyl aminoborane (DMAB). The reducing agent bath reduces Te and TeO₂ into soluble species. As an inorganic sulfurization bath, the passivation bath comprises ammonium sulfide, sulfur, zinc salts, and bases such as NaOH, KOH, and/or TMAH. The inorganic sulfurization bath can be used at pH levels ranging from about 11 to about 13, and at temperatures ranging from about 25° C. to about 50° C. The inorganic sulfurization bath accomplishes inorganic surface sulfurization by generating a CdₓZnₓ₋₁S-containing surface that is more oxidation-resistant than CdTe. As an organic sulfurization bath, the passivation bath generally contains organic sulfur compounds such as thiols. In some embodiments, the organic sulfurization bath contains mercaptopropionic acid (MPA), thioglycerol (TGC), and/or mercaptoethylamine (MEA), as well as zinc salts, and bases such as NaOH, KOH, and/or TMAH. The organic sulfurization bath can be used at pH levels ranging from about 11 to about 13, and at temperatures ranging from about 25° C. to about 50° C. The organic sulfurization bath accomplishes organic sulfur capping by generating a sulfide surface that is more oxidation-resistant than CdTe.

The surface passivation bath, in any embodiment, may further comprise an oxidizer, such as H₂O₂, or, alternatively, a reducing agent. Suitable reducing agents include TMA-BH₄, NaBH₄, and DMAB. Any embodiment of the passivation bath may further comprise pH-adjusting chemicals including, but not limited to, HCl, TMAH, NaOH, or KOH. Once the surface has been passivated by reduction or sulfurization, Ar sputtering in H₂-containing gases such as forming gases (Ar+H₂) can be undertaken to enable residual surface oxide removal without ion-induced oxidation of CdTe. Additionally, plasma cleaning may be conducted, either in-situ or down-stream.

In one embodiment, the passivation bath comprises (NH₄)₂S, CH₃CSNH₂, and ZnSO₄. The pH ranges from about 11 to about 13, and the bath is used in a temperature range of from about 20° C. to about 50° C. In another embodiment, the passivation bath comprises MPA, TGC, and MEA, the pH ranges from about 11 to about 13, and the bath is used in a temperature range of from about 20° C. to about 50° C. In another embodiment, the passivation bath comprises TMA-BH₄ and DMAB, has a pH ranging from about 12 to about 14, and is used at temperatures ranging from about 20° C. to about 70° C.

The various embodiments of the surface passivation bath can be combined in a multi-step process. By way of non-limiting example, CdTe substrates can be washed with a reducing agent surface passivation bath, then washed with an inorganic sulfurization surface passivation bath if acceptable electrical properties are not achieved from the reducing agent bath, then washed with an organic sulfurization surface passivation bath if acceptable electrical properties are not achieved from the inorganic sulfurization surface passivation bath. Other multi-step surface passivation methods comprising the use of various embodiments of the alkaline chemical surface passivation bath described herein are possible. Alternatively, the various embodiments of the surface passivation bath can be combined in a single chemical bath for simultaneous passivation through multiple mechanisms.

Also provided herein is a method for depositing back contacts onto semiconductor materials. The method begins with surface cleaning of semiconductor materials through any of the surface cleaning methods described above. If the surface cleaning produces acceptable electrical properties, then the semiconductor materials are surface passivated by reducing agents. If the reducing agent passivation yields semiconductor materials with acceptable electrical properties, the process proceeds to depositing of the back contacts. If not, the process continues to surface passivation by inorganic sulfurization, as described above. If the inorganic sulfurization yields semiconductor materials with acceptable electrical properties, the process proceeds to depositing of the back contacts through a suitable deposition process. If not, the process continues to surface passivation by organic sulfur capping. If the organic sulfur capping yields semiconductor materials with acceptable electrical properties, the process proceeds to depositing of the back contacts through a suitable deposition process. If not, the process continues with plasma cleaning of the semiconductor materials. Finally, the back contacts are deposited through a suitable deposition process to manufacture solar cells.

It is envisioned that any of the chemical baths described herein can be packaged in the form of a kit comprising a single or separate containers. For instance, a kit could be made housing two containers, one container comprising a surface cleaning bath and the other container comprising a surface passivation bath. Many other kits are possible, such as a kit comprising a cleaning bath component, a reducing agent passivation bath component, an inorganic sulfurization bath component, and an organic sulfurization bath component. Another non-limiting example is a kit for the preparation of a single wet chemical cleaning and passivation bath, comprising an oxidizer component, a first chelating agent component, a second chelating agent component, and a sulfurization component. The kits typically further include instructions for using the components of the kit to practice the subject methods. The instructions for practicing the subject methods are generally recorded on a suitable recording medium. For example, the instructions may be present in the kits as a package insert or in the labeling of the container of the kit or components thereof. In other embodiments, the instructions are present as an electronic storage data file present on a suitable computer readable storage medium, such as a CD-ROM or diskette. In other embodiments, the actual instructions are not present in the kit, but means for obtaining the instructions from a remote source, such as via the internet, are provided. An example of this embodiment is a kit that includes a web address where the instructions can be viewed and/or from which the instructions can be downloaded. As with the instructions, this means for obtaining the instructions is recorded on a suitable substrate.

By “washing” with a cleaning and/or passivation bath, the applicants intend to include any manner of subjecting, exposing, or contacting a substrate to the bath. By way of non-limiting example, the substrate may be at least partially submerged in the bath by dipping it into the bath, or the bath can be applied to the substrate by spraying, coating, painting, flowing, or otherwise allowing the bath to contact at least a portion of the CdTe substrate. Also, the substrates can be subjected to surface cleaning and/or passivation in a continuous process, such as by conveyer continuously carrying the substrates into and out of a bath or baths, or in a batch process. The skilled practitioner will further recognize that one or more of the surface cleaning baths described herein can be used in a sequential method with one or more of the surface passivation baths described herein. In addition, one or more of the surface cleaning baths can be combined into a single wet chemical bath with one or more of the sulfurization passivation baths.

### EXAMPLE 1

Two alkaline cleaning bath solutions comprising ethylenediamine (ED) as the first chelating agent component, and having ED concentrations and pHs of 0.2 M and 12.0, and 1.0 M and 12.35, respectively, were tested against a HCl etch bath. The experiments were conducted at room-temperature using one-inch by one-inch coupons. After cleaning, the substrates were visually observed and subjected to x-ray fluorescence spectroscopy (XRF). XRF counts were calculated from integrating raw peak areas, where blank tests showed no Cd and Te signals. Roughness measurements were performed using surface profilometry. The following Table 1 shows the results of washing CdTe substrates with these two ED baths:

TABLE 1

| Cleaning | Duration | XRF Count | | Roughness | Visual |
|---|---|---|---|---|---|
| Chemistry | (min.) | Cd | Te | (nm) | Observation |
| No Clean | | 383.4 | 1825.3 | 108.63 | |
| 3.7 wt % HCl | 240 | N/A | N/A | N/A | CdTe gone |
| 0.2M ED, | 1050 | 322.4 | 1805 | 108.97 | Center region |
| pH = 12.0 | | | | | darker |
| 1.0M ED, | 960 | 340.5 | 2053.6 | 95.75 | Center region |
| pH = 12.35 | | | | | much darker |

As shown in Table 1, the HCl etch bath removed the CdS layer and induced CdTe lift-off, making it a poor solution for surface cleaning, while the ED surface cleaning with extended duration (>16 hours) did not worsen the CdTe surface roughness. In fact, a slight surface polishing was observed following the 1 M ED cleaning, with the center region of the material becoming much darker. The ED washing produced a significantly lower CdTe etch rate, likely from selective surface oxide removal. FIGS. 1A and 1B show SEM images and EDX analysis of the CdTe film after the extended duration ED cleaning at room temperature. From these images it can be deduced that the degree of CdTe attack by extended cleaning in ED solutions depends on the ED concentration. Severe surface etching produced a heavily oxidized Te-rich layer in 1.0 M ED (quantitatively similar to NP etch), but 0.2 M ED produced minimal surface etching with no stoichiometry change seen by EDX.

### EXAMPLE 2

A series of cleaning baths comprising ED at varying concentrations and pH levels were tested against a HCl bath for efficiency following physical vapor deposition. For this experiment, the chamber was heated up to 100° C., the substrates were left idle in the chamber for 45 minutes, and a ZnTe cap of 200 Å was deposited. The samples tested are listed in the following Table 2:

TABLE 2

| | | | | | | DI H₂O | | |
|---|---|---|---|---|---|---|---|---|
| | | | | | | Immer- | DI H₂O | |
| Sam- | Chem- | Conc. | | Temp. | Time | sion | Rinse | N₂ |
| ple | ical | (M) | pH | (° C.) | (sec.) | (sec.) | (sec.) | Dry |
| 1 | HCl | 1.2 | 0 | 20 | 10 | 10 | 30 | Yes |
| 2 | ED | 1 | 12.4 | 20 | 30 | 10 | 60 | Yes |
| 3 | ED | 1 | 12.4 | 20 | 60 | 10 | 60 | Yes |
| 4 | ED | 1 | 11 | 20 | 30 | 10 | 60 | Yes |
| 5 | ED | 1 | 11 | 20 | 60 | 10 | 60 | Yes |
| 6 | ED | 0.2 | 12 | 20 | 60 | 10 | 60 | Yes |
| 7 | ED | 0.2 | 12 | 20 | 120 | 10 | 60 | Yes |

The ED bath produced about 0.3% higher efficiency than HCl wet clean for many samples. Improvement in efficiency was observed with increasing contact time up to 60 seconds. The best average result was obtained from the sample cleaned with an alkaline bath comprising 1 M ED at a pH of 12.35 for 60 seconds.

### EXAMPLE 3

Two substrates were tested using four cleaned cells each, in a PVD test lay-out. These samples are described by the following Table 3:

TABLE 3

| | | | | | | | DI | | Post- |
|---|---|---|---|---|---|---|---|---|---|
| | | | | | | DI H₂O | H₂O | | Cleaning |
| | | Conc. | | Temp. | Time | Immersion | Rinse | N₂ | Visual |
| Sample | Chemical | (M) | pH | (° C.) | (sec.) | (sec.) | (sec.) | Dry | Observation |
| 1 | HCl | 1.2 | 0 | 20 | 10 | 10 | 30 | Yes | Hydrophilic, |
| | | | | | | | | | water beads |
| | | | | | | | | | up |
| 2 | ED | 1 | 12.35 | 20 | 30 | 10 | 60 | Yes | Hydrophilic, |
| | | | | | | | | | water sheets |
| 3 | ED | 1 | 12.35 | 20 | 60 | 10 | 60 | Yes | Hydrophilic, |
| | | | | | | | | | water sheets |
| 4 | ED | 1 | 12.35 | 20 | 120 | 10 | 60 | Yes | Hydrophilic, |
| | | | | | | | | | water sheets |
| 5 | ED | 2 | 12.65 | 20 | 15 | 10 | 60 | Yes | Hydrophilic, |
| | | | | | | | | | water sheets |
| 6 | ED | 2 | 12.65 | 20 | 30 | 10 | 60 | Yes | Hydrophilic, |
| | | | | | | | | | water sheets |
| 7 | ED | 2 | 12.65 | 20 | 60 | 10 | 60 | Yes | Hydrophilic, |
| | | | | | | | | | water sheets |
| 8 | ED | 2 | 12.65 | 20 | 120 | 10 | 60 | Yes | Hydrophilic, |
| | | | | | | | | | water sheets |

All the ED-cleaned cells, except the shunted ones, showed efficiencies close to or slightly better than the HCl-cleaned cells, and well above the non-cleaned performance of 8.5-9.5%. Moreover, no adverse effect was seen for ED cleaning, suggesting minimal or no efficiency-killing residue was left on the surface after cleaning. Inorganic or organic chemical impurities present as much as 0.1% in the incoming ED (non-electronic grade, 99.9% purity) do not appear to kill the efficiency.

### EXAMPLE 4

A CdTe film was oxidized using H₂O₂ in ED baths. All experiments were performed at room temperature, using 1.0 M ED+2 vol. % H₂O₂, and the pH was adjusted using HCl solution when needed. The CdTe film was completely etched off the surface. The time needed for CdTe removal, and the CdTe etch rate calculated from these examples, are shown is FIGS. 4A and 4B. As seen from these experiments, the oxidized CdTe etch rate depends on the pH of the ED solution. A pH of from about 9.5 to about 12.0 is optimal for faster removal. Additionally, it can be seen from FIG. 2B that the oxide removal rate for 1.0 M ED is faster than that of 2.0 M ED.

Thus, certain aspect of this invention include:

1. A surface cleaning and passivation bath comprising:

a first chelating agent component selected from an amine, an amine derivative, or mixtures thereof; optionally, a second chelating agent component having a poly-hydroxy-carboxylic acid; and a passivation component comprising a source of sulfur.

2. The surface cleaning and passivation bath of claim 1, the first chelating agent component being a Cd chelator.

3. The surface cleaning and passivation bath of claim 1, the first chelating agent component being selected from a polyamine, a poly-alcohol amine, an amino-carboxylic acid, or mixtures thereof.

4. The surface cleaning and passivation bath of claim 1, the first chelating agent component being chosen from the group consisting of: ethylenediamine, diethylenetriamine, triethylenetetramine, tetraethylenepentaamine, pentaethylenehexamine, ethylenediamine tetraacetic acid, iminodiacetic acid, nitriloacetic acid, hydroxyethylenediaminetriacetic acid, diethylenetriaminepentaacetic acid, monoethanolamine, diethanolamine, triethanolamine, 1,2-diphenylethanolamine, triethanolamine, borane-dimethylamine, and mixtures thereof.

5. The surface cleaning and passivation bath of claim 1, further comprising a second chelating agent component, the second chelating agent component being a Te chelator.

6. The surface cleaning and passivation bath of claim 1, further comprising a second chelating agent component selected from poly-hydroxy-carboxylic acids having between 1 and 3 hydroxyl groups and between 1 and 3 carboxyl groups.

7. The surface cleaning and passivation bath of claim 6, the poly-hydroxy-carboxylic acid being chosen from the group consisting of: citric acid, isocitric acid, tartaric acid, glycolic acid, and mixtures thereof.

8. The surface cleaning and passivation bath of claim 1, the pH of the bath being in the range of from about 9 to about 13.

9. The surface cleaning and passivation bath of claim 1, further comprising a pH modifier selected from the group consisting of: HCl, TMAH, NaOH, KOH, and mixtures thereof.

10. The surface cleaning and passivation bath of claim 1, the source of sulfur being an organic sulfur-containing compound.

11. The surface cleaning and passivation bath of claim 1, the source of sulfur being a thiol.

12. The surface cleaning and passivation bath of claim 1, the source of sulfur being selected from mercaptopropionic acid, thioglycerol, mercaptoethylamine, or mixtures thereof.

13. The surface cleaning and passivation bath of claim 1, the source of sulfur consisting essentially of (NH₄)₂S.

14. The surface cleaning and passivation bath of claim 1, the passivation component further comprising a zinc salt.

15. The surface cleaning and passivation bath of claim 14, the zinc salt being ZnSO₄.

16. The surface cleaning and passivation bath of claim 1, the first chelating agent component being present at a concentration ranging from about 0.02 M to about 1 M.

17. The surface cleaning and passivation bath of claim 1, the first chelating agent component being present at a concentration ranging from about 0.1 M to about 0.5 M.

18. The surface cleaning and passivation bath of claim 1, further comprising a second chelating agent component present at a concentration ranging from about 0.02 M to about 1 M.

19. The surface cleaning and passivation bath of claim 1, further comprising a second chelating agent component present at a concentration ranging from about 0.1 M to about 0.5 M.

20. A surface cleaning bath comprising:

a first chelating agent component selected from an amine, an amine derivative, or mixtures thereof; and optionally, a second chelating agent having a poly-hydroxy-carboxylic acid.

21. The surface cleaning bath of claim 20, the first chelating agent component being a Cd chelator.

22. The surface cleaning bath of claim 20, the first chelating agent component selected from a polyamine, a poly-alcohol amine, an amino-carboxylic acid, or mixtures thereof.

23. The surface cleaning bath of claim 20, the first chelating agent component consisting essentially of a compound chosen from the group consisting of: ethylenediamine, diethylenetriamine, triethylenetetramine, tetraethylenepentaamine, pentaethylenehexamine, ethylenediamine tetraacetic acid, iminodiacetic acid, nitriloacetic acid, hydroxyethylenediaminetriacetic acid, diethylenetriaminepentaacetic acid, monoethanolamine, diethanolamine, triethanolamine, 1,2-diphenylethanolamine, borane-dimethylamine, triethanolamine, and mixtures thereof.

24. The surface cleaning bath of claim 20, further comprising a second chelating agent component being a Te chelator.

25. The surface cleaning bath of claim 20, further comprising a second chelating agent component selected from poly-hydroxy-carboxylic acids having between 1 and 3 carboxyl groups and between 1 and 3 hydroxyl groups.

26. The surface cleaning bath of claim 20, further comprising a second chelating agent chosen from citric acid, isocitric acid, tartaric acid, glycolic acid, or mixtures thereof.

27. The surface cleaning bath of claim 20, further comprising an oxidizer.

28. The surface cleaning bath of claim 27, the oxidizer consisting essentially of H₂O₂.

29. The surface cleaning bath of claim 20 further comprising a pH modifier selected from HCl, TMAH, NaOH, KOH, or mixtures thereof, in sufficient amount to maintain the pH between about 9 and about 13.

30. The surface cleaning bath of claim 20, the pH of the surface cleaning bath ranging from about 9 to about 12.

31. A surface passivation bath comprising:

a source of sulfur;

a zinc salt; and

one or more bases.

32. The surface passivation bath of claim 31, the source of sulfur being an organic sulfur-containing compound.

33. The surface passivation bath of claim 31, the source of sulfur being a thiol.

34. The surface passivation bath of claim 31, the source of sulfur being selected from mercaptopropionic acid, thioglycerol, mercaptoethylamine, or mixtures thereof.

35. The surface passivation bath of claim 31, the source of sulfur consisting essentially of (NH₄)₂S.

36. The surface passivation bath of claim 31, the pH of the bath ranging from about 9 to about 13.

37. The surface passivation bath of claim 31, further comprising a pH modifier selected from HCl, TMAH, NaOH, KOH, or mixtures thereof.

38. The surface passivation bath of claim 31, the one or more bases being selected from NaOH, KOH, TMAH, or combinations thereof.

39. The surface passivation bath of claim 31, the zinc salt consisting essentially of ZnSO₄.

40. A method of surface cleaning comprising subjecting II-VI substrates to a solution comprising (i) an amine, an amine derivative, or mixtures thereof, and (ii) a poly-hydroxy-carboxylic acid; the solution having a pH in the range of from about 9 to about 12.5.

41. A method of surface cleaning and passivation comprising washing II-VI substrates in a solution comprising (i) an amine, an amine derivative, or mixtures thereof, (ii) a poly-hydroxy-carboxylic acid, and (iii) a source of sulfur.

42. A method for surface cleaning and passivating a II-VI semiconductor substrate, the method comprising:

cleaning a II-VI semiconductor substrate with a cleaning solution comprising at least one chelating agent; and passivating the surface-cleaned II-VI semiconductor substrate with a passivation solution comprising a source of sulfur, zinc salts, and one or more bases.

43. The method of claim 42 further comprising a Ar sputtering or plasma cleaning step following the surface passivation step.

44. The method of claim 42, the chelating agent being selected from an amine, an amine derivative, a poly-hydroxy-carboxylic acid, or mixtures thereof.

45. A method of surface passivation comprising contacting a CdTe substrate with a passivation solution, the passivation solution comprising a source of sulfur and a zinc salt.

46. The method of claim 45, the source of sulfur being an organic sulfur-containing compound.

47. The method of claim 45, the source of sulfur being a thiol.

48. The method of claim 45, the source of sulfur being selected from mercaptopropionic acid, thioglycerol, mercaptoethylamine, or mixtures thereof.

49. The method of claim 45, the source of sulfur consisting essentially of (NH₄)₂S.

50. The method of claim 45, the zinc salt consisting essentially of ZnSO₄.

51. A method of depositing a back contact on a semiconductor material comprising:

cleaning a semiconductor material with a cleaning solution comprising at least one chelating agent; passivating the semiconductor material with a passivation solution comprising a source of sulfur; optionally, plasma cleaning the semiconductor material; and depositing a back contact on the semiconductor material.

52. A method for depositing back contacts on semiconductor materials comprising:

(i) surface cleaning a semiconductor material;

(ii) passivating the surface of the surface-cleaned semiconductor material with reducing agents; and

(iii) depositing back contacts onto the surface-cleaned and surface-passivated semiconductor material.

53. The method of claim 52, further comprising the step of passivating the surface of the surface-cleaned semiconductor material by inorganic sulfurization, after step (ii);

54. The method of claim 53, further comprising the step of passivating the surface of the surface-cleaned semiconductor material substrates by organic sulfur capping, after the inorganic sulfurization step.

55. The method of claim 54 further comprising the step of plasma cleaning the surface-cleaned semiconductor material, after the organic sulfur capping step.

56. A method of modulating the surface stoichiometry of a CdTe substrate, the method comprising:

washing a CdTe substrate in a solution, the solution having a pH ranging from about 9 to about 12 and comprising (i) an amine component selected from an amine, an amine derivative, or mixtures thereof, and (ii) a poly-hydroxy-carboxylic acid component selected from poly-hydroxy-carboxylic acids having between 1 and 3 hydroxy groups and between 1 and 3 carboxyl groups, and mixtures thereof; and adjusting the ratio of the amine component to the poly-hydroxy-carboxylic acid component in order to modulate the surface stoichiometry.

57. A method of modulating the surface stoichiometry of a CdTe substrate, the method comprising:

washing a CdTe substrate in a solution, the solution comprising (i) an amine, an amine derivative, or mixtures thereof, and (ii) a poly-hydroxy-carboxylic acid; and adjusting the pH of the solution within the range of about 9 to about 12, in order to modulate the surface stoichiometry.

### Phosphorus-Containing Chelator Compounds

Provided herein are methods and compositions for the surface cleaning of semiconductor materials, such as CdTe substrates usable in solar cells. A single wet chemical bath is provided for simultaneous surface cleaning and passivation. Optionally, after the surface cleaning and passivation, the cleaned and passivated semiconductor materials can be subjected to Ar sputtering or a plasma cleaning step to further improve the surface cleaning and passivation. Other suitable cleaning steps, such as exposing the semiconductor materials to ultraviolet radiation, are also possible.

The cleaning and passivation bath described herein contains a phosphorous-containing chelating agent component chosen from suitable phosphorous-containing organic compounds. Suitable phosphorous-containing organic compounds include, but are not limited to: phosphonic acids, meaning compounds having a C—PO(OH)₂ or C—PO(OR)₂ group where R is alkyl or aryl, specifically including N-containing phosphonic acids, and their salts; phosphoric acids, such as orthophosphoric acid, pyrophosphoric acid, tripolyphosphoric acid, tetrapolyphosphoric acid, trimetaphosphoric acid, and phosphoric anhydride; and esters of phosphonic or phosphoric acids. In certain embodiments, the phosphorous-containing chelating agent is one or more phosphonic acids.

In particular, the phosphorous-containing chelating agent component is selected from nitrilotris(methylene)triphosphonic acid, methylphosphonic acid, 1-hydroxyethane-1,1,diylbisphosphonic acid (HEDP), dichloromethylenebisphosphonic acid, aminomethanephosphonic acid, N-(phosphonomethyl)glycine, imino-N,N-bis(methylenephosphonic acid), N-ethylamino-N,N-bis(methylenephosphonic acid), nitrilotris(methylenephosphonic acid), 1,2-diaminoethane-N,N,N′,N′-tetrakis-(methylenephosphonic acid), diethylenetriamine-N,N,N′,N″,N″-penta(methylenephosphonic acid), or mixtures thereof. The phosphorous-containing chelating agent component is generally present in a concentration ranging from about 0.02 M to about 1 M, or more particularly about 0.2 M to about 0.5 M, but other concentrations are possible.

The phosphorous-containing chelating agent component is designed to chelate both Group II and Group VI semiconductor atoms, including Cd and Te, as well as passivate the surface of a CdTe substrate by reducing or preventing surface re-oxidation. Because the phosphorous-containing organic compounds can generally chelate both Cd and Te, a second chelating agent component is typically not necessary. However, the skilled practitioner will recognize that a second chelating agent component such as a poly-hydroxy-carboxylic acid, containing from 1 to 3 hydroxyl groups and from 1 to 3 carboxyl groups, could be added to the bath. In certain embodiments, the second chelating agent component is citric acid, tartaric acid, glycolic acid, isocitric acid, or a mixture thereof. The second chelating agent component primarily chelates Group VI atoms, such as Te, and may be present in a concentration ranging from about 0.02 M to about 1 M, or more particularly from about 0.1 M to about 0.5 M.

The cleaning and passivation bath may further comprise an oxidizer. The oxidizer is generally H₂O₂, but other oxidizers are possible. The oxidizer can be present in concentrations ranging from about 0 M to about 0.05 M, such as about 0.044 M. It should be noted that the presence of an oxidizer in the bath is not necessary to accomplish surface cleaning and/or passivation. The cleaning and passivation bath may further comprise additional pH modifiers such as HCl, tetramethylammonium hydroxide (TMAH), NaOH, KOH, or combinations thereof. However, no additional buffer is needed for cleaning and passivation; the cleaning and passivation bath of the present disclosure can be prepared at any pH and can be used at any pH to surface clean and passivate semiconductor materials. The bath can generally be used at temperatures ranging from about 0° C. to about 80° C., such as about 20° C.

In one embodiment of the cleaning and passivation bath, the phosphorous-containing chelating agent component is nitrilotri(methylphosphonic) acid (N(CH₂PO(OH)₂)₃, or NTMP), and the component is present at a concentration ranging from about 0.2 M to about 0.5 M. The pH of the bath can be adjusted by a KOH buffer, and ranges from about 11.5 to about 13.0. The oxidizer is H₂O₂, and is present at a concentration ranging from about 0 to about 0.044 M. When CdTe substrates are washed with this particular embodiment of the cleaning and passivation bath for a time period of from about 30 seconds to about 60 seconds, the bath shows strong chelating for Cd dissolution. Without wishing to be bound by theory, it is believed the NTMP acts as a H₂O₂ stabilizer. However, the H₂O₂ does not need to be present in this embodiment for the bath to still clean and passivate the surface of CdTe substrates.

In another embodiment of the cleaning and passivation bath, the phosphorous-containing chelating agent component 1-hydroxyethane-1,1-diylbiphosphonic acid (HEDP), and the component is present at a concentration of from about 0.2 M to about 0.5 M. The pH of the cleaning and passivation bath can be adjusted by a KOH buffer, and ranges from about 11.5 to about 13.0. The oxidizer is H₂O₂ and is present at a concentration ranging from about 0 to about 0.044 M. When CdTe substrates are washed with this particular embodiment of the cleaning and passivation bath for a time period of from about 30 seconds to about 60 seconds, the bath shows strong chelating for Cd dissolution. Without wishing to be bound by theory, it is believed the HEDP acts as a H₂O₂ stabilizer. However, the H₂O₂ does not need to be present in this embodiment for the bath to still clean and passivate the surface of CdTe substrates.

Furthermore, the cleaning and passivation bath described herein may allow for surface organic contamination removal and oxide removal in a single wet chemical bath. The removal of surface oxides may improve efficiency of solar cells manufactured from the cleaned semiconductor materials. Surface passivation against re-oxidation in air of CdTe surfaces that have been wet-cleaned to remove organic contamination and surface oxides is further desired in order to improve the overall solar cell manufacturing process robustness and the panel manufacturing yield. Surface oxidation resistance is dictated by the chemical identity of the adsorbed cleaning chemical remaining on the surface, not the surface stoichiometry after cleaning. The surface adsorption of phosphorous-containing organic compounds, such as phosphonic acids, results in surface chemical passivation against re-oxidation in air that slows down water and oxygen attack of the resulting surface obtained from the wet cleaning. The adsorption of phosphorous-containing organic compounds may provide electronic passivation as well. For example, washing a CdTe substrate having a near-stoichiometric surface with a NTMP bath at pH 10 produces greater photoluminescence intensity than washing with HCl does. In this manner, the cleaning and passivation bath of the present disclosure provides surface electronic passivation against surface recombination.

FIG. 5 is a graph comparing the effectiveness of surface passivation by HCl, NTMP, and HEDP cleaning baths. CdTe substrates were washed with HCl, NTMP, and HEDP baths, respectively, and then exposed to air for 30 minutes. As seen in this figure, the CdTe substrates washed with the NTMP bath around pH 11 developed a significantly smaller quantity of Te oxides than the other substrates. FIG. 6 shows X-ray photoelectron spectroscopy (XPS) spectra obtained from CdTe substrates washed with HCl, HEDP, and NTMP. These spectra, having significant peaks in the area where phosphate species absorb (about 133 eV), indicate a relatively high amount of phosphates were absorbed, leaving a low amount remaining on the CdTe surface, after cleaning and passivation with HEDP or NTMP baths. Similar surface chemical passivation via organic phosphonic acid chemisorptions can provide anti-oxidation resistance to any II-VI semiconductor, including CdTe, CdS, CdSe, ZnTe, ZnSe, ZnS, MgTe, MgS, MgSe, and their mixtures.

The cleaning and passivation described herein can be followed by any further suitable cleaning step such as vacuum Ar sputtering in H₂-containing gases (such as Ar+H₂) to enable residual surface oxide removal without ion-induced oxidation of CdTe, and/or H₂ plasma cleaning conducted either in-situ or down-stream.

In order to adjust surface stoichiometry to a desired ratio, the Cd and Te removal rates can be tuned by varying the pH of the bath, the concentration of the chelating agent components, the concentration of oxidizers, and/or the temperature of the bath. Therefore, provided herein are methods of modulating the surface stoichiometry of a semiconductor material. In one example, there is provided herein a method for modulating the surface stoichiometry of a semiconductor material involving subjecting the semiconductor material to a cleaning and passivation bath as described above, and adjusting the pH of the bath in order to achieve the desired surface ratio. As FIG. 3 demonstrates, it is possible to achieve stoichiometric surface ratios using the bath of the present disclosure in a pH range of from about 9 to about 12. Though not wishing to be bound by theory, it is believed this occurs in CdTe substrates because cadmium tends to oxidize into Cd(OH)₂ and CdO faster at higher pH levels, and these compounds do not chelate as readily as Cd does. As a result, CdTe substrates tend to have Cd-rich surfaces at pH levels between about 11 and 13. Conversely, CdTe substrates tend to have Te-rich surfaces at pH levels below about 9. In another example, the concentration of the second chelating agent, if present, can be adjusted in order to achieve a desired stoichiometric ratio on the surface of the semiconductor material.

The ability to modulate surface stoichiometry provides the ability to optimize back-contact surface chemical and electronic properties. For instance, surface stoichiometry control enables the use of various back-contact electrodes that would perform the best with different surface Cd:Te ratios. As seen from FIG. 4, the surface stoichiometry directly affects the efficiency of CdTe substrates. CdTe substrates with stoichiometric surfaces generally show the highest efficiency gain. Better Schottky barriers can be obtained on stoichiometric surfaces.

Additionally, grain boundary attack during cleaning can be minimized by factors such as pH, chelating agent concentration, and the time duration for the surface cleaning and/or passivation process. Minimized grain boundary attack can reduce the chance of cell shunting, which may ultimately improve the panel manufacturing yield and produce higher currents by reducing the carrier recombination at the back-contact.

Further provided is a method for depositing a back contact onto a semiconductor material. The method begins with surface cleaning and passivation of a semiconductor material through use of a surface cleaning and passivation bath as described above. If the cleaning and passivation yields substrates with less-than-desired electrical properties, the method continues to an Ar sputtering or plasma cleaning step. If, however, the cleaning and passivation yields substrates with the desired electrical properties, no secondary cleaning and passivation step is performed. Then, the back contacts are deposited onto the semiconductor material through a suitable deposition process.

The skilled practitioner will recognize that washing a CdTe substrate with a cleaning and passivation bath can be undertaken in any of a number of ways. For example, the substrate may be at least partially submerged in the bath by dipping it into the bath, or the bath can be applied to the substrate by spraying, coating, painting, flowing, or otherwise allowing the bath to contact at least a portion of the substrate. Also, the substrates can be subjected to surface cleaning and passivation in a continuous process, such as by conveyer continuously carrying the substrates into and out of a bath or baths, or in a batch process. The skilled practitioner will further recognize that multiple embodiments of the surface cleaning and passivation bath described herein can be used together in a sequential or simultaneous fashion.

Thus, certain aspect of this invention include:

1. A surface cleaning and passivation bath comprising a phosphorous-containing chelating agent component, the phosphorous-containing chelating agent component consisting essentially of a phosphorous-containing organic compound at a concentration ranging from about 0.02 M to about 1 M.

2. The surface cleaning and passivation bath of claim 1, the phosphorous-containing organic compound being selected from phosphonic acids, phosphoric acids, esters of phosphonic acids, esters of phosphoric acids, or mixtures thereof.

3. The surface cleaning and passivation bath of claim 1, the phosphorous-containing organic compound being a phosphonic acid.

4. The surface cleaning and passivation bath of claim 1, the phosphorous-containing organic compound being chosen from the group consisting of: nitrilotris(methylene)triphosphonic acid, methylphosphonic acid, 1-hydroxyethane-1,1,diylbisphosphonic acid, dichloromethylenebisphosphonic acid, aminomethanephosphonic acid, N-(phosphonomethyl)glycine, imino-N,N-bis(methylenephosphonic acid), N-methylamino-N,N-bis(methylenephosphonic acid), nitrilotris(methylenephosphonic acid), 1,2-diaminoethane-N,N,N′,N′-tetrakis-(methylenephosphonic acid), 1,4,7-triazaheptane-N,N,N′,N″,N″-pentakis(methylenephosphonic acid), diethylenetriamine-N,N,N′,N″,N″-penta(methylenephosphonic acid, and mixtures thereof.

5. The surface cleaning and passivation bath of claim 1, the phosphorous-containing organic compound being chosen from NTMP, HEDP, or combinations thereof.

6. The surface cleaning and passivation bath of claim 1, further comprising an oxidizer.

7. The surface cleaning and passivation bath of claim 5, the oxidizer consisting essentially of H₂O₂.

8. The surface cleaning and passivation bath of claim 1, the pH of the surface cleaning and passivation bath ranging from about 9 to about 13.

9. The surface cleaning and passivation bath of claim 1, the pH of the surface cleaning and passivation bath ranging from about 0 to about 9.

10. The surface cleaning and passivation bath of claim 1, further comprising a pH modifier selected from TMAH, NaOH, KOH, or combinations thereof in sufficient amount to maintain the pH between about 9 and about 13.

11. The surface cleaning and passivation bath of claim 1, further comprising HCl in sufficient amount to maintain the pH between about 0 and about 9.

12. The surface cleaning and passivation bath of claim 1, the concentration of the phosphorous-containing organic compound ranging from about 0.2 M to about 0.5 M.

13. A method of surface cleaning and passivation comprising contacting a semiconductor material with a solution comprising a phosphorous-containing organic compound.

14. The method of claim 13, the semiconductor material comprising a II-VI semiconductor

15. The method of claim 13, the semiconductor material comprising CdTe.

16. The method of claim 13, the phosphorous-containing organic compound being selected from phosphonic acids, phosphoric acids, esters of phosphonic acids, esters of phosphoric acids, or mixtures thereof.

17. The method of claim 13, the phosphorous-containing organic compound being a phosphonic acid.

18. The method of claim 13, the phosphorous-containing organic compound being chosen from the group consisting of: nitrilotris(methylene)triphosphonic acid, methylphosphonic acid, 1-hydroxyethane-1,1,diylbisphosphonic acid, dichloromethylenebisphosphonic acid, aminomethanephosphonic acid, N-(phosphonomethyl)glycine, imino-N,N-bis(methylenephosphonic acid), N-methylamino-N,N-bis(methylenephosphonic acid), nitrilotris(methylenephosphonic acid), 1,2-diaminoethane-N,N,N′,N′-tetrakis-(methylenephosphonic acid), 1,4,7-triazaheptane-N,N,N′,N″,N″-pentakis(methylenephosphonic acid), diethylenetriamine-N,N,N′,N″,N″-penta(methylenephosphonic acid, and mixtures thereof.

19. The method of claim 13, the phosphorous-containing organic compound being chosen from NTMP, HEDP, or combinations thereof.

20. The method of claim 13, the solution having a pH ranging from about 9 to about 13.

21. The method of claim 13, the solution having a pH ranging from about 0 to about 9.

22. The method of claim 13, further comprising the step of depositing a back contact onto the semiconductor material.

23. A method of modulating the surface stoichiometry of a semiconductor material, the method comprising subjecting the semiconductor material to a solution comprising a phosphorous-containing organic compound and an oxidizer, and adjusting or maintaining the pH of the solution, the oxidizer concentration, or both, to achieve a desired surface stoichiometry.

24. The method of claim 23, the semiconductor material comprising CdTe.

25. The method of claim 23, the pH being adjusted to a level between about 9 and about 11.

26. The method of claim 23, the phosphorous-containing organic compound being selected from phosphonic acids, phosphoric acids, esters of phosphonic acids, esters of phosphoric acids, or mixtures thereof.

27. The method of claim 23, the phosphorous-containing organic compound being a phosphonic acid.

28. The method of claim 23, the phosphorous-containing organic compound being chosen from the group consisting of: nitrilotris(methylene)triphosphonic acid, methylphosphonic acid, 1-hydroxyethane-1,1,diylbisphosphonic acid, dichloromethylenebisphosphonic acid, aminomethanephosphonic acid, N-(phosphonomethyl)glycine, imino-N,N-bis(methylenephosphonic acid), N-methylamino-N,N-bis(methylenephosphonic acid), nitrilotris(methylenephosphonic acid), 1,2-diaminoethane-N,N,N′,N′-tetrakis-(methylenephosphonic acid), 1,4,7-triazaheptane- N,N,N′,N″,N″-pentakis(methylenephosphonic acid), diethylenetriamine-N,N,N′,N″,N″-penta(methylenephosphonic acid, and mixtures thereof.

29. The method of claim 23, the phosphorous-containing organic compound being chosen from NTMP, HEDP, or combinations thereof.

30. The method of claim 23, the phosphorous-containing organic compound being present at a concentration ranging from about 0.02 M to about 1 M.

31. The method of claim 23, the phosphorous-containing organic compound being present at a concentration ranging from about 0.2 M to about 0.5 M.

32. A method of passivating the surface of a semiconducter material against surface recombination, the method comprising contacting the semiconductor material with a surface cleaning and passivation bath of claim 1.

33. The method of claim 32, wherein the semiconductor material comprises CdTe.

Certain embodiments of the surface cleaning and passivation methods and compositions of the present disclosure are defined in the examples herein. It should be understood that these examples, while indicating particular embodiments of the invention, are given by way of illustration only. From the above discussion and these examples, one skilled in the art can ascertain the essential characteristics of this disclosure, and without departing from the spirit and scope thereof, can make various changes and modifications to adapt the compositions and methods described herein to various usages and conditions. Various changes may be made and equivalents may be substituted for elements thereof without departing from the essential scope of the disclosure. In addition, many modifications may be made to adapt a particular situation or material to the teachings of the disclosure without departing from the essential scope thereof.

What is claimed is:

1. A surface cleaning bath comprising:
a first chelating agent component selected from an amine, an amine derivative, or mixtures thereof; and
optionally, a second chelating agent having a poly-hydroxy-carboxylic acid.

2. The surface cleaning bath of claim 1, the first chelating agent component being a Cd chelator selected from a polyamine, a poly-alcohol amine, an amino-carboxylic acid, or mixtures thereof.

3. The surface cleaning bath of claim 1, the first chelating agent component consisting essentially of a compound chosen from the group consisting of: ethylenediamine, diethylenetriamine, triethylenetetramine, tetraethylenepentaamine, pentaethylenehexamine, ethylenediamine tetraacetic acid, iminodiacetic acid, nitriloacetic acid, hydroxyethylenediaminetriacetic acid, diethylenetriaminepentaacetic acid, monoethanolamine, diethanolamine, triethanolamine, 1,2-diphenylethanolamine, borane-dimethylamine, triethanolamine, and mixtures thereof.

4. The surface cleaning bath of claim 1, further comprising a second chelating agent component being a Te chelator selected from poly-hydroxy-carboxylic acids having between 1 and 3 carboxyl groups and between 1 and 3 hydroxyl groups.

5. The surface cleaning bath of claim 1, further including a passivation component comprising a source of sulfur, the source of sulfur being an organic sulfur-containing compound.

6. The surface cleaning bath of claim 5, the source of sulfur being selected from mercaptopropionic acid, thioglycerol, mercaptoethylamine, or mixtures thereof.

7. The surface cleaning bath of claim 1, further including a passivation component comprising a source of sulfur the source of sulfur consisting essentially of (NH₄)₂S.

8. A surface passivation bath comprising:
a source of sulfur;
a zinc salt; and
one or more bases.

9. The surface passivation bath of claim 8, the source of sulfur being an organic sulfur-containing compound selected from mercaptopropionic acid, thioglycerol, mercaptoethylamine, or mixtures thereof.

10. The surface passivation bath of claim 8, the source of sulfur consisting essentially of (NH₄)₂S.

11. A method of surface cleaning and passivation comprising washing II-VI substrates in a solution of a surface cleaning bath according to claim 5.

12. A method of surface passivation comprising contacting a CdTe substrate with a passivation solution according to claim 8.

13. A method for surface cleaning and passivating a II-VI semiconductor substrate, the method comprising:
cleaning a II-VI semiconductor substrate with a cleaning solution comprising a surface cleaning bath according to claim 20; and
passivating the surface-cleaned II-VI semiconductor substrate with a passivation solution comprising a source of sulfur, zinc salts, and one or more bases.

14. A surface cleaning and passivation bath comprising a phosphorous-containing chelating agent component, the phosphorous-containing chelating agent component consisting essentially of a phosphorous-containing organic compound at a concentration ranging from about 0.02 M to about 1 M.

15. The surface cleaning and passivation bath of claim 14, the phosphorous-containing organic compound being selected from phosphonic acids, phosphoric acids, esters of phosphonic acids, esters of phosphoric acids, or mixtures thereof.

16. The surface cleaning and passivation bath of claim 14, the phosphorous-containing organic compound being chosen from the group consisting of: nitrilotris(methylene)triphosphonic acid, methylphosphonic acid, 1-hydroxyethane-1,1,diylbisphosphonic acid, dichloromethylenebisphosphonic acid, aminomethanephosphonic acid, N-(phosphonomethyl)glycine, imino-N,N-bis(methylenephosphonic acid), N-methylamino-N,N-bis(methylenephosphonic acid), nitrilotris(methylenephosphonic acid), 1,2-diaminoethane-N,N,N′,N′-tetrakis-(methylenephosphonic acid), 1,4,7-triazaheptane- N,N,N′,N″,N″-pentakis(methylenephosphonic acid), diethylenetriamine-N,N,N′,N″,N″-penta(methylenephosphonic acid, and mixtures thereof.

17. The surface cleaning and passivation bath of claim 14, further comprising an oxidizer.

18. The surface cleaning and passivation bath of claim 14, further comprising a pH modifier selected from TMAH, NaOH, KOH, or combinations thereof in sufficient amount to maintain the pH between about 9 and about 13.

19. The surface cleaning and passivation bath of claim 14, further comprising HCl in sufficient amount to maintain the pH between about 0 and about 9.
